(19) United States
(12) Patent Application Publication
(10) Pub. No.: US 2016/0027669 A1
(43) Pub. Date: Jan. 28, 2016

(54) Wet Etching Apparatus and the Etching Method Thereof

(71) Applicant: Shenzhen China Star Optoelectronics Technology Co. Ltd., Shenzhen, Guangdong (CN)

(72) Inventor: Jia LI, Shenzhen, Guangdong (CN)

(73) Assignee: Shenzhen China Star Optoelectronics Technology Co. Ltd., Shenzhen, Guangdong (CN)

(21) Appl. No.: 14/396,048

(22) PCT Filed: Jul. 24, 2014
(86) PCT No.: PCT/CN2014/082939

§ 371 Date: Oct. 21, 2014

(30) Foreign Application Priority Data
Jul. 22, 2014 (CN) 201410351266.0

(51) Int. Cl. H01L 21/67

(52) U.S. Cl. CPC H01L 21/67086

(57) ABSTRACT

The present invention discloses wet etching apparatus, which comprises an etching tank, multiple rollers provided inside the etching tank, immersion tank and a lifter. The multiple rollers are used to carry a substrate to be etched. Wherein, the immersion tank is provided inside the etching tank and below the rollers, the lifter is provided on the lower surface of the bottom plate of the etching tank, and the lifter pushes the immersion tank up or down, so that the substrate to be etched is immersed in or out of the etchant in the immersion tank. The present invention can fill the immersion tank with new etchant while the multiple rollers transfer the substrate to the etching tank, which is beneficial to shorten the immersing and etching time.

### BACKGROUND OF THE INVENTION

1. Field of the Invention

The present invention relates to the fields of wet etching technology, and in particular to a wet etching apparatus and the etching method thereof.

2. The Related Arts

Wet etching process refers an etching technique using liquid chemical agent to remove etching composition. Wet etching is using a suitable etchant to have chemical reaction with the etching composition, which changes the structure of the etching composition. Therefore, the portion without photoresist coated is removed from the surface of the substrate, and the portion coated with photoresist is preserved, so that the surface of the substrate has the desired pattern.

During the manufacturing process of the liquid crystal display panel, the wet etching mode for the glass substrate mainly includes spray mode and dip mode.

In the traditional dip mode, as shown in FIG. 1, the wet etching apparatus comprises an etching tank 11 and multiple parallel rollers 12 provided inside the etching tank 11. Wherein, valves 13 are provided on the left and right side plates of the etching tank 11. After the glass substrate 14 to be etched is transferred to the etching tank 11 by the rollers 12, it cannot proceed with immersing and etching the glass substrate 14 until the etching tank 11 is filled with the chemical etchant, which is not beneficial to shorten the immersing and etching time. Moreover, with immersing and etching, the active ingredient of the chemical etchant in the etching tank 11 changes rapidly. Therefore, the chemical etchant in the etching tank 11 can not be exhausted completely through the valves 13 of the etching tank 11, leading to the poor replacement capability of the chemical etchant. The chemical etchant in the etching tank 11 will deteriorate after prolonged accumulation, which affects the etching quality to the glass substrate 14.

### SUMMARY OF THE INVENTION

In order to solve the above technical issue, the embodiment according to the present invention provides a wet etching apparatus, which comprises an etching tank and multiple rollers provided inside the etching tank, the multiple rollers being used to carry a substrate to be etched; wherein, the wet etching apparatus further comprising an immersion tank and a lifter; wherein, the immersion tank is provided inside the etching tank and below the rollers, the lifter is provided on the lower surface of the bottom plate of the etching tank, and the lifter pushes the immersion tank up or down, so that the substrate to be etched is immersed in or out of the etchant in the immersion tank.

Furthermore, the thicknesses of the first side plate and the second side plate of the immersion tank are both smaller than the minimum spacing between any two of the rollers.

Furthermore, both the first side plate and the second side plate of the immersion tank drop down in the vertical direction, so that the top surfaces of the first side plate and the second side plate are as high as or below the upper surface of the bottom plate of the etching tank, and then the used etchant in the immersion tank is completely exhausted.

Furthermore, the wet etching apparatus further comprises a first solenoid valve and a second solenoid valve, the first solenoid valve is provided on the first side plate, which is used to control the first side plate up or down, and the second solenoid valve is provided on the second side plate, which is used to control the second side plate up or down.

Furthermore, the immersion tank is made of polyvinyl chloride material.

Furthermore, the outer surface of the lifter is packed with corrosion-resistant material.

Furthermore, the outer surfaces of first solenoid valve and the second solenoid valve are packed with corrosion-resistant material.

The present invention further provides an etching method of the wet etching apparatus, comprising using multiple rollers to transfer a substrate to be etched to the etching tank, and filling the immersion tank of the wet etching apparatus with etchant; using the lifter to push the immersion tank up, so that the substrate to be etched is immersed in the etchant in the immersion tank and proceed to be etched.

Furthermore, the etching method further comprises: using the lifter to push the immersion tank down after finishing etching the substrate to be etched, so that the etched substrate is out of the etchant.

Furthermore, the etching method comprises: dropping down the first side plate and the second side plate of the immersion tank in the vertical direction, so that the top surfaces of the first side plate and the second side plate are as high as or below the upper surface of the bottom plate of the etching tank, and then the used etchant in the immersion tank is completely exhausted.

The wet etching apparatus and the etching method thereof according to the present invention fill the immersion tank with new etchant while the multiple rollers transfer the substrate to the etching tank. Therefore, it doesn't need to wait until the substrate is transferred to the etching tank by the multiple rollers, and then fills the immersion tank with etchant, which is beneficial to shorten the immersing and etching time. Moreover, the wet etching apparatus and the etching method thereof according to the present invention can completely exhaust the used etchant from the immersion tank, which avoids the deterioration of the etchant due to the poor exchange capacity of the etchant in the immersion tank.

### BRIEF DESCRIPTION OF THE DRAWINGS

Through the detailed descriptions accompanying drawings as follows, other aspects, features, and advantages of the embodiment of the present invention will become clearer.

FIG. 1 is a schematic view illustrating the structure of the wet etching apparatus according to the existing technology;

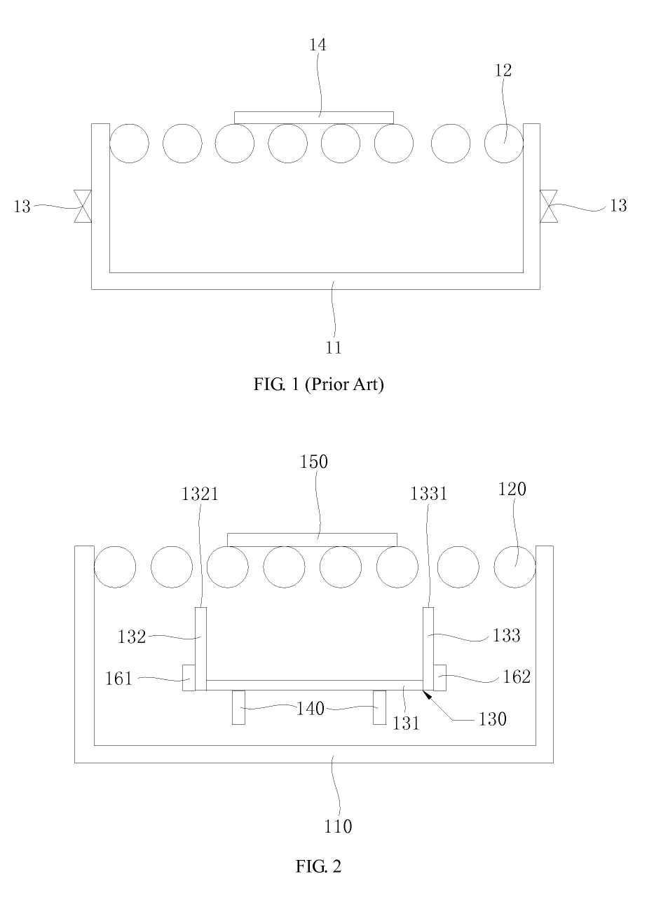

FIG. 2 is a schematic view illustrating the structure of the wet etching apparatus according to the embodiment of the present invention; and

FIGS. 3a to 3d respectively show the etching flow diagrams of using the wet etching apparatus according to the embodiment of the present invention to etch substrate.

### DETAILED DESCRIPTION OF THE PREFERRED EMBODIMENTS

The detailed descriptions according to the preferred embodiment of the present invention are as follows. However, the present invention can be carried out in many different forms, which should not be construed as limited to the specific embodiments set forth herein. On the contrary, these embodiments are provided to explain the principles of the present invention and the practical applications thereof, so that those having ordinary skills in the art can understand various embodiments in the present invention and various modifications suited to the particular intended application.

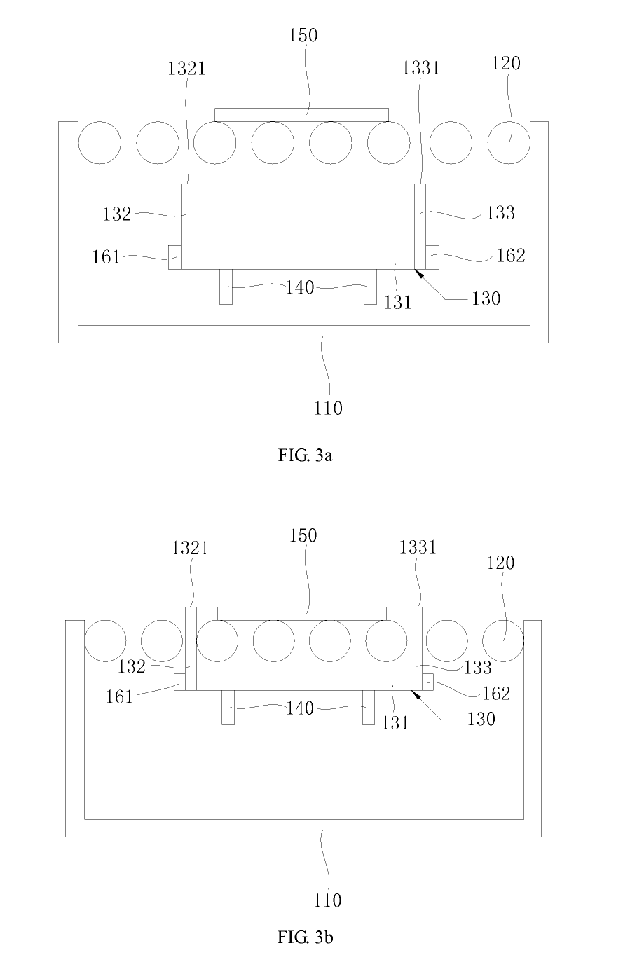

FIG. 2 is a schematic view illustrating the structure of the wet etching apparatus according to the embodiment of the present invention.

Referring to FIG. 2, the wet etching apparatus according to the present invention comprises: an etching tank 110, multiple rollers 120, an immersion tank 130 and a lifter 140.

The multiple rollers 120 are provided in the etching tank 110, which is used to carry a substrate (ex. glass substrate) 150 to be etched and to transfer the substrate 150 to the etching tank 110. The immersion tank 130 is provided in the etching tank 110 and below the multiple rollers 120. The lifter 140 can be cylinder, which is provided on the lower surface of the bottom plate 131 of the etching tank 130 and pushes the immersion tank 130 up or down, so that the substrate 150 to be etched is immersed in or out of the etchant in the immersion tank 130. It can fill the immersion tank 130 with new etchant while the multiple rollers 120 transfer the substrate 150 to the etching tank 110. Therefore, it doesn't need to wait until the substrate 150 is transferred to the etching tank 110 by the multiple rollers 120, and then fills the immersion tank 130 with etchant, which is beneficial to shorten the immersing and etching time. Moreover, in order to let the etchant in the immersion tank 130 immerse and etch the substrate 150, in the present embodiment, preferably, the thicknesses of the first side plate 132 and the second side plate 133 of the immersion tank are both smaller than the minimum spacing between any two of the rollers 120. The minimum spacing between any two of the rollers 120 is equal to the distance between the centers of any two of the rollers 120 minus the diameter of the roller 120.

Moreover, in order to completely exhaust the used etchant from the immersion tank 130 to avoid the deterioration of the etchant due to the poor exchange capacity of the etchant in the immersion tank 130, in the present embodiment, the first side plate 132 and the second side plate 133 of the immersion tank 130 drop down in the vertical direction, so that the top surface 1321 of the first side plate 132 and the top surface 1331 of the second side plate 133 are as high as or below the upper surface of the bottom plate 131 of the etching tank, and then the used etchant in the immersion tank 130 is completely exhausted. It should be understand that the first side plate 132 and the second side plate 133 can rise up in the vertical direction after the used etchant in the immersion tank 130 is completely exhausted, and the immersion tank 130 restores to the original status. In order to push the first side plate 132 and the second side plate 133 up or down in the vertical direction, in the present embodiment, a first solenoid valve 161 and a second solenoid valve 162 are respectively provided on the first side plate 132 and the second side plate 133. The first solenoid valve 161 and the second solenoid valve 162 respectively control the first side plate 132 and the second side plate 133 up or down in the vertical direction. It should be understood that the present invention is not limited thereto. For example, it can also utilize the cylinder to control the first side plate 132 and the second side plate 133 up or down in the vertical direction. In addition, in order to avoid the corrosion of the first solenoid valve 161 and the second solenoid valve 162 from the etchant in the etching tank 110, in the present embodiment, preferably, the outer surfaces of first solenoid valve 161 and the second solenoid valve 162 are packed with corrosion-resistant material, such as perfluoroalkoxy resin (referred to as the PFA) material.

Moreover, in the present embodiment, because the stored etchant in the immersion tank 130 have corrosion properties, preferably, the immersion tank 130 according to the present embodiment is made of polyvinyl chloride material. Of course, the present invention is not limited thereto, it may also be made of other suitable corrosion-resistant material, such as perfluoroalkoxy resin (referred to as the PFA) material.

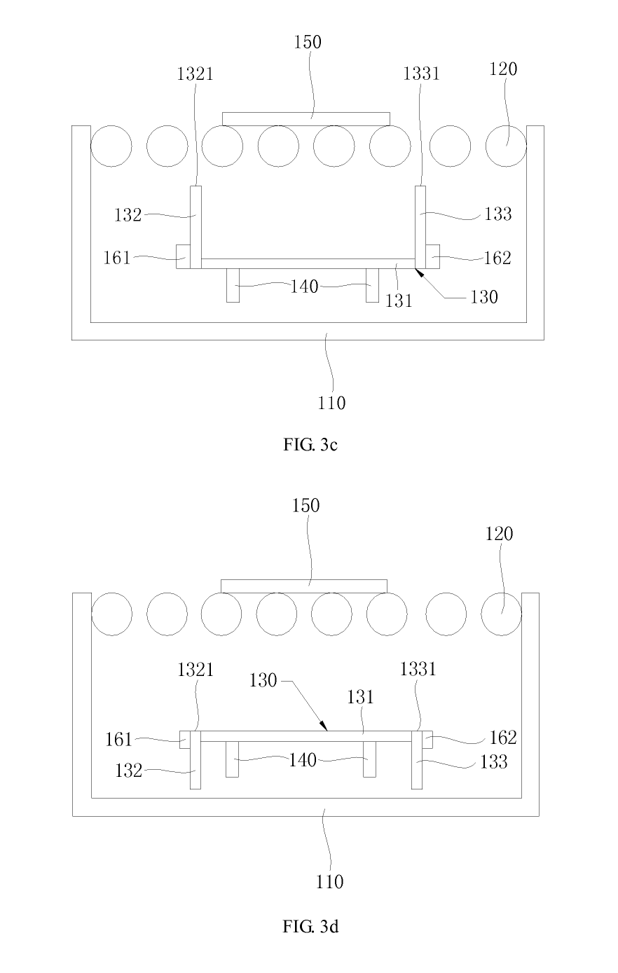

FIGS. 3a to 3d respectively show the etching flow diagrams of using the wet etching apparatus according to the embodiment of the present invention to etch substrate.

In FIG. 3a, it fills the immersion tank 130 with etchant while the multiple rollers 120 transfer the substrate 150 to the etching tank 110. Therefore, it doesn't need to wait until the substrate 150 is transferred to the etching tank 110 by the multiple rollers 120, and then fills the immersion tank 130 with etchant, which is beneficial to shorten the immersing and etching time.

In FIG. 3b, it utilizes the lifter 140 to push the immersion tank 130 up, so that the substrate 150 is immersed in the immersion tank 130 full of etchant and proceed to be immersed and etched.

In FIG. 3c, it uses the lifter 140 to push the immersion tank 130 down after finishing etching the substrate 150, so that the etched substrate 150 is out of the immersion tank 130 full of the etchant. After that, it can use the multiple rollers 120 to transfer the etched substrate 150 out the etching tank 110 and into the next process (such as washing process or drying process).

In FIG. 3d, it drops down the first side plate 132 and the second side plate 133 of the immersion tank 130 in the vertical direction, so that the top surface 1321 of the first side plate 132 and the top surface 1331 of the second side plate 133 are as high as or below the upper surface of the bottom plate 131 of the etching tank, and then the used etchant in the immersion tank 130 is completely exhausted. After that, the first side plate 132 and the second side plate 133 of the immersion tank 130 can rise up in the vertical direction, and the immersion tank 130 restores to the original status. It fills the immersion tank 130 with new etchant while the multiple rollers 120 transfer the next substrate to the etching tank 110. Therefore, the used etchant in the immersion tank 130 is completely exhausted and then fill with new etchant after etching substrate every time, which avoids the deterioration of the etchant due to the poor exchange capacity of the etchant in the immersion tank 130.

The present invention are mentioned above referring to the specific embodiments, but for those having ordinary skills in the art, those modifications and variations are considered encompassed in the scope of protection defined by the clams of the present invention.

What is claimed is:

1. A wet etching apparatus, comprising an etching tank and multiple rollers provided inside the etching tank, the multiple rollers being used to carry a substrate to be etched; wherein, the wet etching apparatus further comprising an immersion tank and a lifter; wherein, the immersion tank is provided inside the etching tank and below the rollers, the lifter is provided on the lower surface of the bottom plate of the etching tank, and the lifter pushes the immersion tank up or down, so that the substrate to be etched is immersed in or out of the etchant in the immersion tank.

2. The wet etching apparatus as claimed in claim 1, wherein the thicknesses of the first side plate and the second side plate of the immersion tank are both smaller than the minimum spacing between any two of the rollers.

3. The wet etching apparatus as claimed in claim 1, wherein both the first side plate and the second side plate of the immersion tank drop down in the vertical direction, so that the top surfaces of the first side plate and the second side plate are as high as or below the upper surface of the bottom plate of the etching tank, and then the used etchant in the immersion tank is completely exhausted.

4. The wet etching apparatus as claimed in claim 2, wherein both the first side plate and the second side plate of the immersion tank drop down in the vertical direction, so that the top surfaces of the first side plate and the second side plate are as high as or below the upper surface of the bottom plate of the etching tank, and then the used etchant in the immersion tank is completely exhausted.

5. The wet etching apparatus as claimed in claim 3, wherein the wet etching apparatus further comprises a first solenoid valve and a second solenoid valve, the first solenoid valve is provided on the first side plate, which is used to control the first side plate up or down, and the second solenoid valve is provided on the second side plate, which is used to control the second side plate up or down.

6. The wet etching apparatus as claimed in claim 4, wherein the wet etching apparatus further comprises a first solenoid valve and a second solenoid valve, the first solenoid valve is provided on the first side plate, which is used to control the first side plate up or down, and the second solenoid valve is provided on the second side plate, which is used to control the second side plate up or down.

7. The wet etching apparatus as claimed in 1, wherein the immersion tank is made of polyvinyl chloride material.

8. The wet etching apparatus as claimed in claim 1, wherein the outer surface of the lifter is packed with corrosion-resistant material.

9. The wet etching apparatus as claimed in claim 5, wherein the outer surfaces of first solenoid valve and the second solenoid valve are packed with corrosion-resistant material.

10. The wet etching apparatus as claimed in claim 6, wherein the outer surfaces of first solenoid valve and the second solenoid valve are packed with corrosion-resistant material.

11. An etching method of the wet etching apparatus, comprising:
using multiple rollers to transfer a substrate to be etched to the etching tank, and filling the immersion tank of the wet etching apparatus with etchant;
using the lifter to push the immersion tank up, so that the substrate to be etched is immersed in the etchant in the immersion tank and proceed to be etched.

12. The etching method as claimed in claim 11, wherein it further comprises:
using the lifter to push the immersion tank down after finishing etching the substrate to be etched, so that the etched substrate is out of the etchant.

13. The etching method as claimed in claim 12, wherein it further comprises:
dropping down the first side plate and the second side plate of the immersion tank in the vertical direction, so that the top surfaces of the first side plate and the second side plate are as high as or below the upper surface of the bottom plate of the etching tank, and then the used etchant in the immersion tank is completely exhausted.
